(19) United States
(12) Patent Application Publication
(10) Pub. No.: US 2005/0184385 A1
(43) Pub. Date: Aug. 25, 2005

(54) Semiconductor device with improved thermal characteristics

(76) Inventors: John McKenna Brennan, Wyomissing, PA (US); Joseph Michael Freund, Fogelsville, PA (US); Sujal Dipak Shah, Fogelsville, PA (US); Richard Handly Shanaman III, Richland, PA (US)

Correspondence Address: Ryan, Mason & Lewis, LLP, 90 Forest Avenue, Locust Valley, NY, 11560, US

(21) Appl. No.: 10/784,756

(22) Filed: Feb. 23, 2004

(51) Int. Cl. H01L 23/10

(52) U.S. Cl. 257/706

(57) ABSTRACT

A semiconductor device includes a substrate and an active region formed in the substrate proximate an upper surface of the substrate. The active region includes at least one circuit element formed therein. At least one channel is formed in a back surface of the substrate opposite the upper surface of the substrate, the channel being formed proximate the active region. The channel is substantially filled with one or more layers of a thermally conductive material and configured so as to provide a thermal conduction path for conducting heat away from the active region.

### FIELD OF THE INVENTION

The present invention relates generally to semiconductor devices, and more particularly relates to techniques for improving a thermal performance of a semiconductor device while maintaining a structural integrity of the device.

### BACKGROUND OF THE INVENTION

Power semiconductor devices, such as, for example, radio frequency (RF) power amplifiers fabricated using a laterally diffused metal-oxide-semiconductor (LDMOS) process technology, can generate junction temperatures in excess of 200 degrees Celsius under normal operation. Consequently, it is critical that the semiconductor devices have sufficient electrical and thermal transfer characteristics so as to efficiently dissipate this heat.

Silicon is commonly used as a substrate in the fabrication of most integrated circuit (IC) dies. Since silicon is a relatively poor thermal conductor compared to, for example, a metal, a power semiconductor device, such as, but not limited to, an RF LDMOS device, is often fabricated on a substantially thin die (e.g., about two thousandths of an inch (mils) thick or less) compared to a traditional die, which is generally about six mils thick or more. This allows greater thermal transfer between the die and a surrounding package to which the die is attached.

While it may be beneficial to utilize thin dies in forming power semiconductor devices to improve thermal performance, a disadvantage of using thin dies is that they often exhibit considerable bowing. This die bow, as it is often referred, results in a substantially non-planar back surface of the dies, thus making it difficult to attach the dies to a package base for providing efficient thermal transfer between the dies and their corresponding packages. Furthermore, the reduced structural rigidity of the thin dies makes them more susceptible to damage, and thus significantly more difficult to handle in production.

From an IC packaging perspective, most power semiconductor devices employ a ceramic IC package. Ceramic IC packages offer excellent thermal transfer properties compared to, for example, plastic packages. However, ceramic packages are expensive, and in amass production environment, the ceramic package becomes a primary manufacturing cost of the packaged semiconductor device. While plastic IC packages are significantly less costly, the plastic package cannot withstand the high temperatures (e.g., about 400 degrees Celsius) typically required for eutectic die attach or soldering, generally used to secure a die to the IC package. Consequently, alternative methodologies, such as, for example, low-temperature solder or thermal epoxy, are often used to attach the die to the plastic package. These alternative die attachment means, however, can significantly reduce the thermal transfer and/or electrical characteristics of the device and are therefore undesirable. Additionally, the die bow often exhibited by thin dies, as stated above, may further reduce the thermal transfer properties of the device, especially when using an epoxy die attach.

There exists a need, therefore, for a semiconductor device which has improved thermal performance and that does not suffer from one or more of the problems exhibited by conventional semiconductor devices.

### SUMMARY OF THE INVENTION

The present invention meets the above-noted need by providing, in an illustrative embodiment, improved techniques for fabricating a semiconductor device including one or more IC dies which are configured to retain the structural rigidity necessary to substantially eliminate the die bow associated with standard thin dies, and yet still achieve the thermal transfer and/or electrical characteristics of thin dies.

In accordance with one aspect of the invention, a semiconductor device includes a substrate and an active region formed in the substrate proximate an upper surface of the substrate. The active region includes at least one circuit element formed therein. At least one channel is formed in a back surface of the substrate opposite the upper surface of the substrate, the channel being formed below the active region. The channel is substantially filled with one or more layers of a thermally conductive material and configured so as to provide a thermal conduction path for conducting heat away from the active region in the semiconductor device. When more than one active region is included in the semiconductor device, one or more corresponding channels maybe formed proximate each of the active regions for providing localized thermal conduction paths for conducting heat away from respective active regions in the device.

In an illustrative embodiment of the invention, a semiconductor device includes a base, and at least one integrated circuit die attached to the base. The integrated circuit die includes a semiconductor substrate and an active region formed in the substrate proximate an upper surface of the substrate, the active region including at least one circuit element formed therein. At least one channel is formed in a back surface of the substrate opposite the upper surface of the substrate, the channel being formed proximate the active region. The channel is substantially filled with at least one layer of a thermally conductive material and configured so as to provide a thermal conduction path between the active region and the base for conducting heat away from the active region.

In accordance with another aspect of the invention, a method for forming a semiconductor device includes the steps of forming one or more active regions in a semiconductor substrate proximate an upper surface of the substrate, the active region including at least one circuit element formed therein, and forming at least one channel in a back surface of the substrate opposite the upper surface of the substrate, the channel being formed proximate the active region. The method further includes filling the channel with at least one layer of a thermally conductive material so as to provide a thermal conduction path for conducting heat away from the active region.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1A is a cross-sectional view illustrating at least a portion of a thin IC die exhibiting die bow of upper and back surfaces of the die.

FIG. 1B is a cross-sectional view illustrating at least a portion of a standard thickness IC die having substantially planar upper and back surfaces.

FIG. 2 is a top perspective view depicting at least a portion of an exemplary IC die, formed in accordance with an illustrative embodiment of the invention.

FIG. 3 is a cross-sectional view depicting at least a portion of a semiconductor device including the exemplary IC die shown in FIG. 2 and a thin IC die attached to a package base, in accordance with one aspect of the invention.

FIG. 4 is a cross-sectional view depicting at least a portion of a semiconductor device including the exemplary IC die shown in FIG. 2 and additional IC dies attached to a thermal carrier, in accordance with another aspect of the invention.

### DETAILED DESCRIPTION OF THE INVENTION

The present invention will be described herein in the context of an illustrative semiconductor device including one or more IC dies. It should be understood, however, that the present invention is not limited to this or any particular semiconductor device arrangement. Rather, the invention is more generally applicable to techniques for advantageously forming an IC die configured to retain the structural rigidity of a die having a more standard thickness, in order to alleviate or substantially eliminate die bow often associated with a thin IC die, and yet still achieve the desirable thermal transfer properties of a thin die.

The term “thin die” as used herein is intended to refer to a semiconductor die having a cross-sectional thickness (e.g., about 2 mils or less) that is substantially less than a more standard semiconductor die, which is typically about 6 mils or more in cross-sectional thickness. As previously stated, many power semiconductor devices, such as, but not limited to, RF LDMOS devices, are often fabricated on thin dies to improve the thermal transfer between the dies and the respective packages to which the dies are attached. Each of the dies is typically attached to a metal base (e.g., copper) in the package which has a significantly higher thermal conductivity compared to silicon.

One disadvantage of utilizing thin IC dies, however, is the reduced structural rigidity of the thin dies. This reduced structural rigidity often results in die bow, as previously explained. FIG. 1A is a cross-sectional view illustrating a thin IC die 100 exhibiting die bow. The amount of die bow exhibited by the die 100 will depend, at least in part, on the physical dimensions (e.g., length and/or width) of the die. As the dimensions of the die increase, the degree of bowing generally increases accordingly. Although an upper surface 102 of the die 100 is shown as having a convex bow and a back surface 104 is shown as having a concave bow, a given thin die may alternatively exhibit bowing in the opposite direction. In either case, however, the back surface 104 of the die 100 will not be planar as a result of the bowing. Consequently, there will be a significant reduction in thermal transfer between the die and a package base to which the back surface 104 of the die 100 is attached, such as, for example, during eutectic die attach, soldering, epoxy, etc. Moreover, the thin die is substantially more vulnerable to damage during handling as a result of a reduced structural integrity of the die.

FIG. 1B illustrates a cross-sectional view of a die 150 having a more standard thickness (e.g., about 6 mils or greater). As apparent from the figure, the increased thickness of the die 150 provides additional structural rigidity, compared to the thin die 100, so as to substantially eliminate bowing of an upper surface 152 and/or back surface 154 of the die. However, the thermal conductivity of silicon, of which the die 150 is most commonly formed, is relatively poor in comparison to, for example, a metal package base to which the die may ultimately be attached. Therefore, heat generated by one or more circuit components formed proximate the upper surface 152 of the die 150 (e.g., in an active region of the die) will not be readily dissipated through the die to the package base which is attached to the back surface 154 of the die.

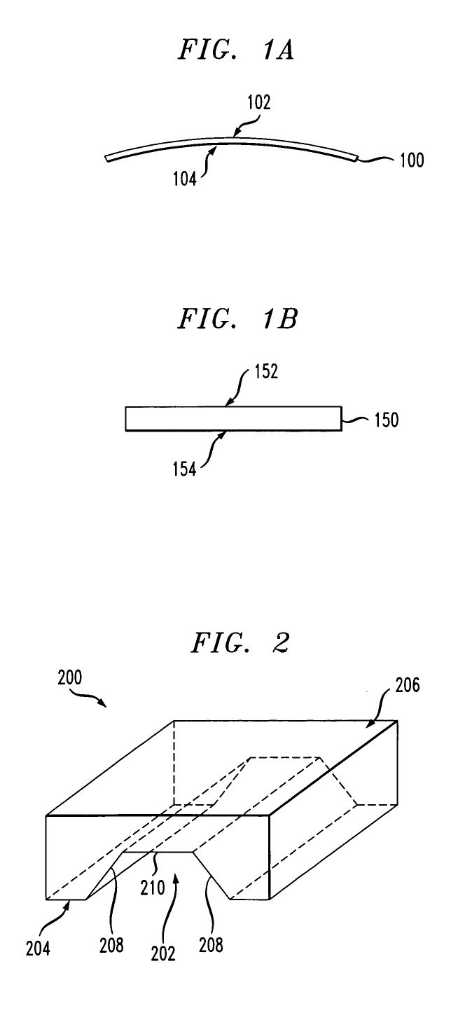

FIG. 2 is a top perspective view depicting an exemplary IC die 200 in which the techniques of the present invention are implemented. An important aspect of the invention is that it provides a methodology for advantageously obtaining the structural rigidity of a die having a more standard thickness (e.g., about 6 mils) while concurrently achieving or surpassing the beneficial thermal transfer properties of a thin die. One way to accomplish this, in accordance with an illustrative embodiment of the invention, is to form at least one channel 202 in a back surface 204 of the IC die 200. The channel 202 may be formed proximate at least one circuit element (not shown) formed in an upper surface 206 of the die 200, and preferably in close relative proximity to a heat generating region in the die. It is to be understood that more than one channel may be formed in the die, particularly when the die comprises a plurality of active regions that may be spaced apart from one another. Assuming a plurality of channels is used, each of the channels may be formed proximate a particular corresponding active region in the die, thereby providing localized thermal conduction paths for beneficially conducting heat away from respective active regions in the die.

The channel 202 preferably comprises a substantially v-shaped groove (v-groove), including sloped sidewalls 208 and a substantially flat top surface 210. As apparent from the figure, the v-groove terminology as used herein is intended to relate more to the slope of the sidewalls 208 of channel 202 than to the overall shape of the channel. The v-grooves may be formed in batch for an entire semiconductor wafer using, for example, an anisotropic etching process, although alternative methodologies are contemplated for forming the channels (e.g., sawing, grinding, etc.).

Anisotropic etching is a well-known technique which can be used to form v-grooves in a semiconductor wafer. The anisotropy of the etching stems from the inherent crystalline structure of the silicon wafer. In silicon, atoms lying predominantly on <111> oriented planes appear more densely packed than those lying on <110> or <100> planes. As a consequence, certain etchants are favored in removing atoms from the <110> and <100> planes. The different etching rates that selected etchants exhibit against the different crystalline planes results in the formation of well-defined and repeatable v-grooves in the wafer where unprotected silicon is exposed to the etchant. A common anisotropic wet etchant may comprise, for example, potassium hydroxide (KOH), tetramethyl amonium hydroxide (TMAH), etc.

It is to be appreciated that the present invention is not limited to a particular shape of the channel 202. The channel shape depends, at least in part, on the fabrication methodology used to form the channel 202. For instance, when sawing is used to form the channel 202, the sidewalls 208 may be substantially straight, rather than sloped as depicted in the figure. Furthermore, the channel 202 need not include a substantially flat top surface 210, but may instead be configured such that the sloped sidewalls 208 converge together at a point. In an alternative embodiment of the invention, the channel may comprise rounded sidewalls, similar to a bowl-shaped structure.

As stated above, the channel 202 is preferably formed in close relative proximity to an active region formed in the upper surface 206 of the die 200. A distance between the top surface 210 of the channel 202 and the active region is preferably substantially equal to a comparative distance between an active region and a back surface of a thin die, typically about 40 micrometers (microns). In this manner, a depth of the channel 202 is preferably configured so as to maximize a tradeoff between structural integrity of the die 200 and thermal transfer properties of the die. In a preferred embodiment, the channel 202 is formed having a depth that is about 2 mils from the upper surface 206 of the die 200.

FIG. 3 is a cross-sectional view depicting at least a portion of an exemplary semiconductor device 300 including an IC die 302 of a more standard thickness (e.g., about 6 mils) in which the techniques of the present invention are implemented. The IC die 302 may comprise a substrate 308 and an epitaxial layer 310 formed on the substrate. One or more circuit elements may be formed in an active region 312 in the epitaxial layer 310 of the die 302. Die 302 comprises at least one channel 314 formed in a back surface of the die, in a manner similar to that previously described in conjunction with FIG. 2. In order to improve the thermal transfer properties of the die 302, as well as the structural integrity of the die, the void in the substrate 308 created by the formation of the channel 314 therein is preferably substantially filled with one or more layers of a thermally conductive material.

The material used to fill the channel 314 preferably has a thermal conductivity that is higher than a thermal conductivity of the substrate material, typically silicon (e.g., greater than about 200 Watts per meter per degree Kelvin (W/m·K)), such as, but not limited to, a metal. The thermally conductive material used to fill the channel 314 may include, for example, silver, gold, aluminum, copper-tungsten, aluminum alloys, etc., and more preferably comprises copper. A conventional deposition (e.g., metal deposition) process may be used to fill the channel 314 with the thermally conductive material, as will be understood by those skilled in the art. A methodology for filling a v-groove with a conductive material is described, for example, in an article by S. Prabhakaran et al., entitled “Fabrication of Thin-Film V-Groove Inductors Using Composite Magnetic Materials,” International Microelectronics and Packaging Society (IMAPS), Advanced Technology Workshop on Passive Integration, pp. 1-4, June 2002, which is incorporated by reference herein.

The material used to fill the channel 314 preferably provides a superior thermal conduction path between the active region 312 of the die 302 and the package base 308, at least compared to the thermal conduction of the silicon substrate 308 alone. For example, the thermal conductivity of copper is about 400 W/m·K, while the thermal conductivity of pure silicon, under the same environmental conditions (e.g., temperature, pressure, etc.), is about 140 W/m·K. Silver has an even higher thermal conductivity (e.g., about 420 W/m·K). The thermal conductivity of silicon decreases as a doping concentration level of the silicon increases. If gallium arsenide (GaAs) is employed as the substrate material, the thermal conductivity would be about 60 W/m·K.

It is beneficial that the channel 314 be filled such that the back surface of the die 302 is substantially planar. Providing a planar back surface of the IC die 302 essentially eliminates any gaps between a die attach layer 316, which is used for attaching the die to the package base 306, and the back surface of the die, thereby improving thermal transfer between the die and the package base. With the channel formed and filled, the die back surface may include additional metal layers deposited thereon for a eutectic die attach (e.g., gold-tin eutectic die attach) to the package base 306. Alternatively, the back surface of the die 302 may be left unmetalized and the die attached to the package base 306 by an epoxy, or other suitable die attach adhesive. With the die bow substantially eliminated, the use of epoxy as a die attach methodology is feasible, therefore advantageously reducing IC assembly cycle time and/or cost.

Preferably, the channel 314 runs the entire length of the die 302, between opposing sides of the die. Forming the channel in this manner provides relief points in the die for the expansion and contraction of the material used to fill channel 314 due to a mismatch in coefficient of thermal expansion (CTE) between the material forming the substrate 308 and the material used to fill the channel. Ideally, the CTE of the material used to fill the channel 314 is substantially the same as the CTE of the material forming the substrate 308, although this is typically not the case. For example, the CTE of silicon is about 2.6 parts per million per degree Kelvin (2.6×10⁻⁶/K), while the CTE of copper is about 16.5×10⁻⁶/K.

The semiconductor device 300 may further include one or more additional IC dies, such as, for example, a standard thin IC die 304 (e.g., about 2 mils in thickness), attached to the same package base 306 as IC die 302 via die attach layer 356. The thin die 304, like die 302, may comprise a substrate 350 and an epitaxial layer 352 formed on the substrate. One or more circuit elements maybe formed in an active region 354 of thin die 304. As previously stated, a distance 318 between the active region 312 in die 302 and a top surface 320 of the filled channel 314 is preferably substantially the same as a distance between the active region 354 in thin die 304 and the package base 306. Thus, die 302 provides thermal transfer properties that are comparable to thin die 304, while retaining the beneficial structural rigidity of a die having a more traditional thickness.

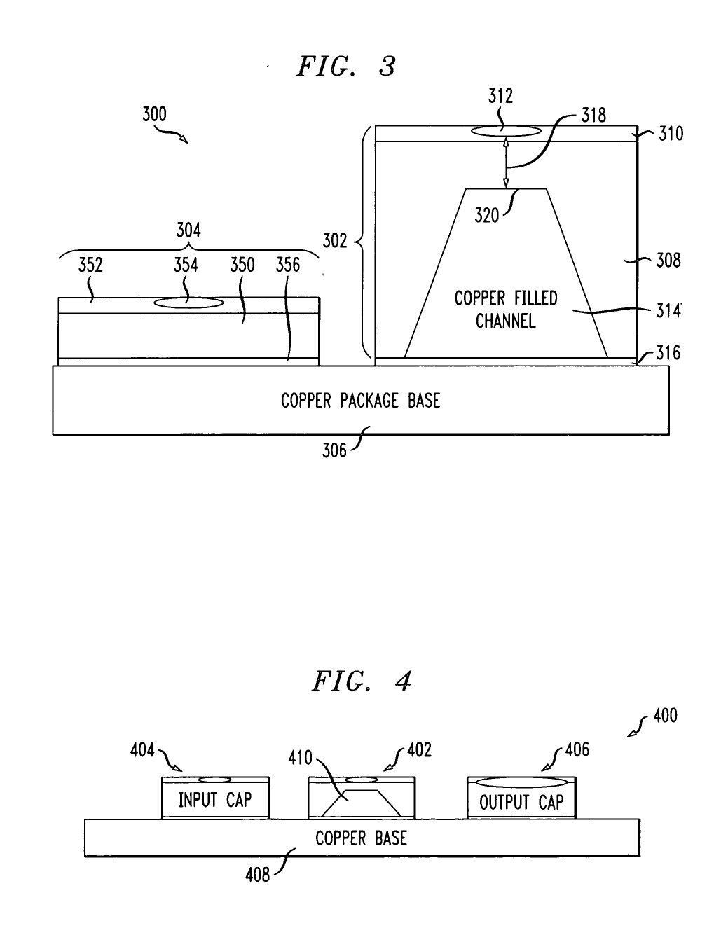

FIG. 4 is a cross-sectional view illustrating a semiconductor device 400 which may comprise a plurality of IC dies 402, 404 and 406 attached to a common package base 408, which may be copper. At least one of the IC dies, namely, IC die 402, comprises a filled channel 410 formed in the bottom surface of the die, as previously described in connection with FIGS. 2 and 3. Preferably, the other IC dies, namely, IC dies 404 and 406, are formed having a cross-sectional thickness that is substantially the same as a cross-sectional thickness of IC die 402, such as, for example, greater than about 6 mils. Making the thicknesses of the IC dies substantially the same ensures that upper surfaces of each die are substantially level with one another, thus making profiles easier to produce compared to using IC dies with differing heights. This facilitates a subsequent wire bonding process.

The techniques of the present invention described herein provide a semiconductor device that advantageously achieves the structural integrity of a standard thickness IC die, thereby alleviating die bow often associated with thin IC dies and reducing damage to the die during handling. Moreover, the semiconductor device formed in accordance with the techniques of the invention, achieves the structural integrity of the standard thickness die while retaining the beneficial thermal characteristics of a thin die by forming one or more channels in the back surface of the die.

It is to be understood that the channel may be formed of various structures, materials, thicknesses and other dimensions, shapes, and/or positioning, some alternatives of which have been previously described herein. For example, the channel formed in the back surface of a given IC die may run horizontal or perpendicular to the direction shown in the figures. Although the channel is shown as having v-shaped sidewalls, the invention is not limited to such an arrangement. Furthermore, while the channel is shown in the figures as running the entire length of the die, between opposing sides of the die, the channel may be formed having a length that is less than the length of the die.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims. claims

1. A semiconductor device, comprising:
a semiconductor substrate;
an active region formed in the substrate proximate an upper surface of the substrate, the active region including at least one circuit element formed therein; and
at least one channel formed in a back surface of the substrate opposite the upper surface of the substrate, the at least one channel being formed proximate the active region;
wherein the at least one channel is substantially filled with at least one layer of a thermally conductive material and configured so as to provide a thermal conduction path for conducting heat away from the active region.

2. The device of claim 1, wherein the at least one channel is filled with the thermally conductive material such that the at least one filled channel is substantially planar with the back surface of the substrate.

3. The device of claim 1, wherein the at least one layer of thermally conductive material comprises a metal.

4. The device of claim 1, wherein the at least one layer of thermally conductive material comprises at least one of copper, aluminum, gold, silver, a copper alloy, and an aluminum alloy.

5. The device of claim 1, wherein the at least one layer of thermally conductive material has a thermal conductivity greater than a thermal conductivity of the substrate.

6. The device of claim 1, wherein the at least one channel comprises one or more sloped sidewalls.

7. The device of claim 1, wherein the at least one channel comprises a substantially v-shaped groove.

8. The device of claim 1, wherein the at least one channel is formed using an etching process.

9. The device of claim 8, wherein the etching process comprises anisotropic etching.

10. The device of claim 1, wherein the at least one channel is formed proximate the active region.

11. The device of claim 1, wherein the at least one channel is formed through a length of the device between opposing sides of the device.

12. The device of claim 1, wherein the at least one layer of thermally conductive material has a coefficient of thermal expansion that is substantially matched to a coefficient of thermal expansion of the substrate.

13. The device of claim 1, wherein the device has a cross-sectional thickness greater than or equal to about six thousandths of an inch.

14. The device of claim 1, further comprising a plurality of active regions formed in the upper surface of the substrate and a plurality of corresponding channels formed in the back surface of the substrate, each of the channels being proximate a corresponding one of the active regions.

15. The device of claim 1, wherein the at least one channel is formed having a maximum height that is about two thousandths of an inch from the upper surface of the substrate.

16. The device of claim 1, wherein the at least one channel is formed having a maximum height that is about forty micrometers from the active region.

17. A method for forming a semiconductor device comprising the steps of:
forming one or more active regions in a semiconductor substrate proximate an upper surface of the substrate, the active region including at least one circuit element formed therein;
forming at least one channel in a back surface of the substrate opposite the upper surface of the substrate, the at least one channel being formed proximate the active region; and
filling the at least one channel with at least one layer of a thermally conductive material so as to provide a thermal conduction path for conducting heat away from the active region.

18. The method of claim 17, wherein the step of forming the at least one channel comprises etching at least a portion of the back surface of the substrate.

19. The method of claim 18, wherein the etching step comprises anisotropic etching.

20. A semiconductor device, comprising:
a base; and
at least one integrated circuit die attached to the base, the at least one integrated circuit die comprising:
a semiconductor substrate;
an active region formed in the substrate proximate an upper surface of the substrate, the active region including at least one circuit element formed therein; and
at least one channel formed in a back surface of the substrate opposite the upper surface of the substrate, the at least one channel being formed proximate the active region;
wherein the at least one channel is substantially filled with at least one layer of a thermally conductive material and configured so as to provide a thermal conduction path between the active region and the base for conducting heat away from the active region.
